(19) United States
(12) Patent Application Publication
(10) Pub. No.: US 2025/0072252 A1
(43) Pub. Date: Feb. 27, 2025

(54) DISPLAY PANEL

(71) Applicant: Shenzhen China Star Optoelectronics Semiconductor Display Technology Co., Ltd., Shenzhen (CN)

(72) Inventors: Yunxia LI, Shenzhen (CN); Shijian QIN, Shenzhen (CN)

(21) Appl. No.: 17/769,730

(22) PCT Filed: Apr. 1, 2022
(86) PCT No.: PCT/CN2022/084776

§ 371 Date: Nov. 14, 2024

(30) Foreign Application Priority Data
Mar. 14, 2022 (CN) 202210244405.4

(51) Int. Cl. H10K 59/35; H10K 59/12; H10K 71/13

(52) U.S. Cl. CPC H10K 59/353; H10K 59/1201; H10K 71/135

(57) ABSTRACT

A display panel is provided, wherein along a second direction, first pixel groups and second pixel groups are alternately arranged to form first pixel rows, and third pixel groups are arranged to form second pixel rows. Further, along a first direction, at least one second pixel row is arranged between every two adjacent first pixel rows. The first-pixel group includes at least two first sub-pixels arranged along the second direction, and the second-pixel group includes at least two second sub-pixels arranged along the second direction.

### FIELD OF DISCLOSURE

The present application relates to a field of printing technologies, and in particular, to a display panel.

### BACKGROUND OF RELATED ARTS

Organic light-emitting diode (OLED) has advantages of all-solid-state, ultra-thin, no viewing angle limitation, fast response times, room temperature operation available, easy to realize flexible display and 3D display, etc., which is unanimously recognized as a mainstream technology for a next-generation display. There are two main ways to form a light-emitting layer of a current OLED, namely, vacuum thermal evaporation and inkjet printing. Compared with vacuum thermal evaporation, inkjet printing does not need a mask, and a material utilization rate can reach 100%.

### SUMMARY

### Technical Problems

High precision printheads used in conventional printing techniques can produce droplets in a size ranging from 1 to 10 pL (picolitre). Higher resolution product requires using smaller, higher-precision printheads, which increases hardware costs. In addition, due to the influence of inkjet accuracy, printing is generally performed along a vertical direction of the printheads, which allows more printheads to dispense ink droplets into sub-pixels. A current pixel arrangement is mainly SBS (side by side) architecture or LB (line bank) architecture. The advantage of the SBS architecture is that it saves more ink materials. However, it requires high inkjet accuracy of the hardware. The LB architecture has low requirements on the accuracy of the vertical printing direction and is more suitable for printing high-resolution products. However, it consumes more ink, and if there is a problem with a retaining wall, a wide range of pixels will be affected, which may affect the product yield.

Therefore, it is urgent to design a new pixel arrangement architecture, which can improve the product yield and be suitable for display panels with higher pixel resolution under the condition that the accuracy of the inkjet printing device remains unchanged.

### Solution to Problem

### Technical Solutions

The present application provides a display panel with a novel pixel arrangement structure, which can improve the yield rate and pixel resolution of products under the condition that the accuracy of the inkjet printing equipment remains unchanged.

The present application provides a display panel, which includes:
a substrate;
a plurality of pixel groups arranged on the substrate and including first pixel groups, second pixel groups, and third pixel groups, wherein the first pixel groups and the second pixel groups are alternately arranged along a second direction to form first pixel rows, the third pixel groups are arranged along the second direction to form second pixel rows, wherein at least one of the second pixel rows is arranged between two adjacent ones of the first pixel rows along a first direction, and wherein the second direction intersects with the first direction;
wherein each first pixel group includes at least two first sub-pixels arranged along the second direction, each second pixel group includes at least two second sub-pixels arranged along the second direction, and each third pixel group includes at least one third sub-pixels arranged along the second direction.

Optionally, in some embodiments of the present application, the first sub-pixels are arranged in two rows along the first direction in the first pixel group, and numbers of the first sub-pixels in each row are equal, wherein the second sub-pixels are arranged in two rows along the first direction in the second pixel group, and numbers of the second sub-pixels in each row are equal, and wherein the third sub-pixels are arranged in a row along the first direction in the third pixel group.

Optionally, in some embodiments of the present application, in the first pixel group and the second pixel group, the first sub-pixels and the second sub-pixels are arranged axially symmetrically, and the first pixel group and the second pixel group are alternately arranged along the first direction.

Optionally, in some embodiments of the present application, the first sub-pixels and the second sub-pixels are arranged axially symmetrically in the first pixel group and the second pixel group, and the first pixel group and the second pixel group are located on different columns along the second direction.

Optionally, in some embodiments of the present application, along the second direction, the display panel includes a first end and a second end disposed opposite to each other, wherein the first pixel group includes a first pixel structure, a second pixel structure, and a third pixel structure, wherein the first pixel structure extends along the first direction, the second pixel structure extends from the first pixel structure to the first end, and the third pixel structure extends from the first pixel structure to the second end, wherein the second pixel structure and the third pixel structure are located on different rows, and wherein the second pixel group has the same structure as the first pixel group;
wherein two of the second pixel rows are arranged between two adjacent ones of the first pixel rows, and each of the third sub-pixels is disposed corresponding to one of the first sub-pixels and one of the second sub-pixels.

Optionally, in some embodiments of the present application, each of the first sub-pixels and each of the second sub-pixels have an equal area.

Optionally, in some embodiments of the present application, the second pixel rows are arranged between two adjacent ones of the first pixel rows, and wherein one of the first sub-pixels, one of the second sub-pixels, and one of the third sub-pixels that are adjacent to each other constitute a pixel unit.

Optionally, in some embodiments of the present application, the first pixel structure includes two of the first sub-pixels arranged along the first direction, both the second pixel structure and the third pixel structure include one of the first sub-pixels, and the third pixel group includes two of the third sub-pixels.

Optionally, in some embodiments of the present application, the first pixel structure includes two of the first sub-pixels arranged along the first direction, both the second pixel structure and the third pixel structure include two of the first sub-pixels arranged along the second direction, and the third pixel group includes two of the third sub-pixels.

Optionally, in some embodiments of the present application, an area of each first sub-pixel is equal to an area of each second sub-pixel, and an area of each third sub-pixel is greater than the area of each first sub-pixel.

Optionally, in some embodiments of the present application, the first sub-pixels are arranged in a row along the first direction in the first pixel group, the second sub-pixels are arranged in a row along the first direction in the second pixel group, and wherein the first pixel rows and the second pixel rows are alternately arranged along the first direction.

Optionally, in some embodiments of the present application, the first pixel group located on two adjacent ones of the first pixel rows are arranged in a one-to-one correspondence or staggered along the first direction.

Optionally, in some embodiments of the present application, the first sub-pixels in the first pixel group are arranged in a row along the first direction, the second sub-pixels in the second pixel group are arranged in a row along the first direction, and in every adjacent four rows of the plurality of pixel groups, two of the second pixel rows are arranged between two of the first pixel rows along the first direction;
wherein the first sub-pixels are one of red sub-pixels or green sub-pixels, the second sub-pixels are another one of the red sub-pixels or the green sub-pixels, and the third sub-pixels are blue sub-pixels, and wherein one of the first sub-pixels, one of the second sub-pixels, and two of the third sub-pixels that are adjacent to each other constitute a pixel unit.

Optionally, in some embodiments of the present application, the first pixel group located on two adjacent ones of the first pixel rows are arranged in a one-to-one correspondence or staggered along the first direction.

Optionally, in some embodiments of the present application, the display panel further includes a first retaining wall and a second retaining wall;
wherein the first retaining wall is disposed on the substrate and is located in a gap between adjacent sub-pixels in one of the plurality of pixel groups, the second retaining wall is disposed on the substrate and is located in a gap between adjacent ones of the plurality of pixel groups, and wherein a height of the first retaining wall is smaller than a height of the second retaining wall.

Optionally, in some embodiments of the present application, the first retaining wall is further located between adjacent ones of the plurality of pixel groups, and the second retaining wall covers at least part of the first retaining wall.

Optionally, in some embodiments of the present application, a height of the first retaining wall ranges from 0.3 to 0.6 μm, and a height of the second retaining wall ranges from 0.9 to 1.2 μm.

Optionally, in some embodiments of the present application, the display panel further includes a plurality of anodes, a plurality of light-emitting layers, and a cathode;
wherein the anodes are arranged on the substrate at intervals, wherein in each of the plurality of pixel groups, the first retaining wall is arranged between two adjacent ones of the anodes, and each of the light-emitting layers is arranged on a side of a corresponding one of the anodes away from the substrate, and wherein the cathode is disposed on a side of one of the light-emitting layers away from the substrate and covers the first retaining wall, the second retaining wall, and the light-emitting layer.

Optionally, in some embodiments of the present application, a height of the light-emitting layer ranges from 10 nm to 200 nm.

Optionally, in some embodiments of the present application, the first pixel groups, the second pixel groups, and the third pixel groups display different colors, respectively.

### ADVANTAGES OF INVENTION

### Beneficial Effects

A display panel is provided. The display panel includes a substrate and a plurality of pixel groups. The pixel groups include first pixel groups, second pixel groups, and third pixel groups. The first pixel groups and the second pixel groups are alternately arranged along a second direction to form first pixel rows, and the third pixel groups are arranged along the second direction to form second pixel rows, wherein at least one second pixel row is arranged between two adjacent ones of the first pixel rows along a first direction. In the present application, the first pixel group includes at least two first sub-pixels arranged along the second direction, and the second pixel groups include at least two second sub-pixels arranged along the second direction. When the inkjet printing is performed along the first direction, in a direction perpendicular to the inkjet printing direction, the printing ranges corresponding to at least the first pixel group and the second pixel group are effectively guaranteed. Thus, the utilization rate of printing nozzles is improved, the inkjet printing time is reduced, and suitable for printing the first sub-pixel and the second sub-pixel with smaller sizes, thereby improving pixel resolution. In addition, since the first pixel group and the second pixel group are located in the first pixel row and are alternately arranged, when the first pixel group, the second pixel group, or the third pixel group is abnormally printed, a wide range of pixel areas will not be affected, thereby improving the product yield.

### BRIEF DESCRIPTION OF DRAWINGS

### Description of Attached Drawings

In order to clearly illustrate the technical solutions in the embodiments of the present application, the following briefly introduces the drawings that need to be used in the description of the embodiments. Obviously, the drawings in the description are only some embodiments of the present application, and for one skilled in the art, other drawings can be obtained from these drawings without doing creative efforts.

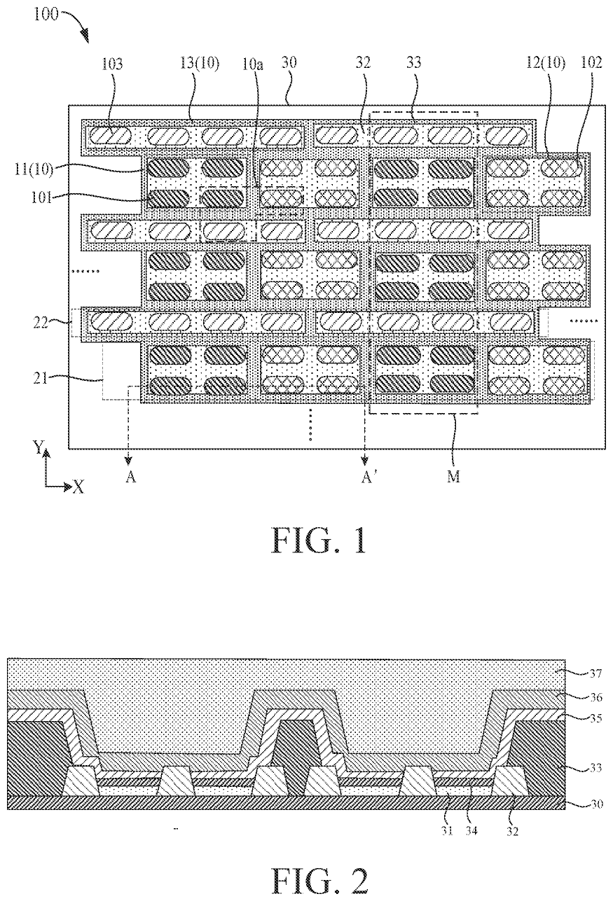

FIG. 1 is a schematic diagram of a first structure of a display panel provided by the present application.

FIG. 2 is a schematic cross-sectional view of the display panel along AA′ in FIG. 1 provided by the present application.

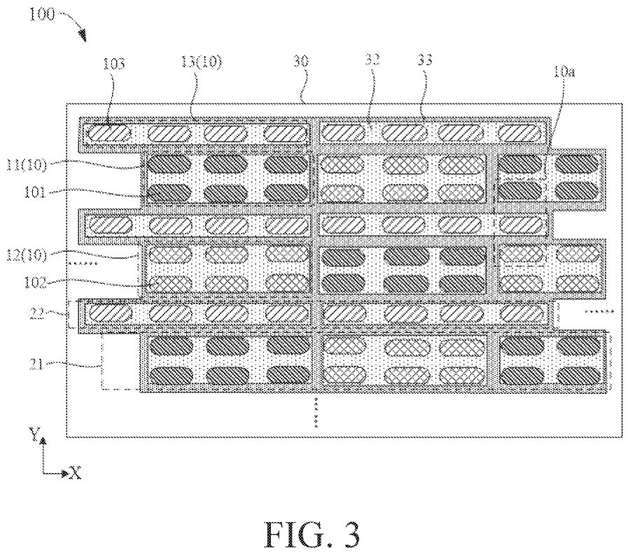

FIG. 3 is a second structural schematic diagram of a display panel provided by the present application.

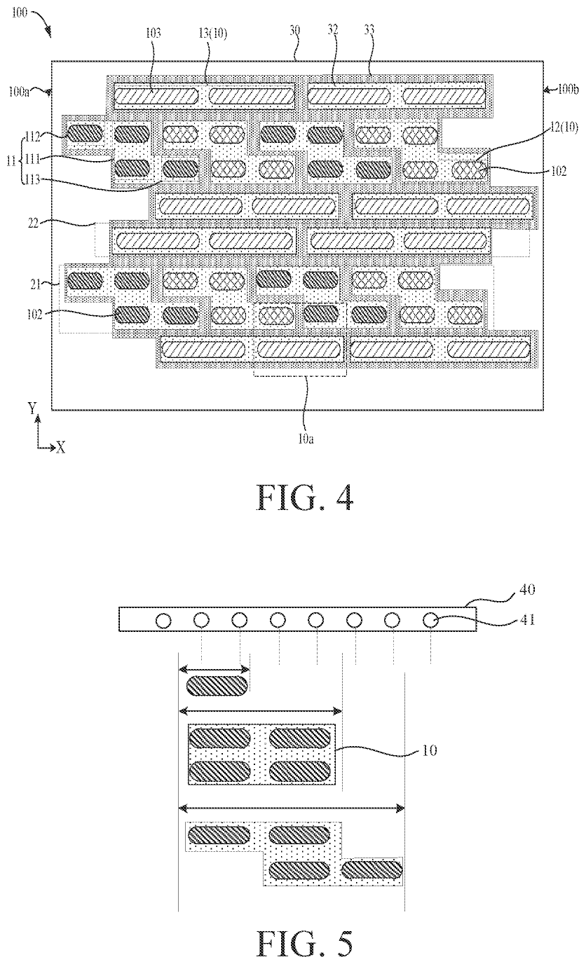

FIG. 4 is a third structural schematic diagram of a display panel provided by the present application.

FIG. 5 is a schematic diagram showing the principle when inkjet printing is performed on the display panel provided by the present application.

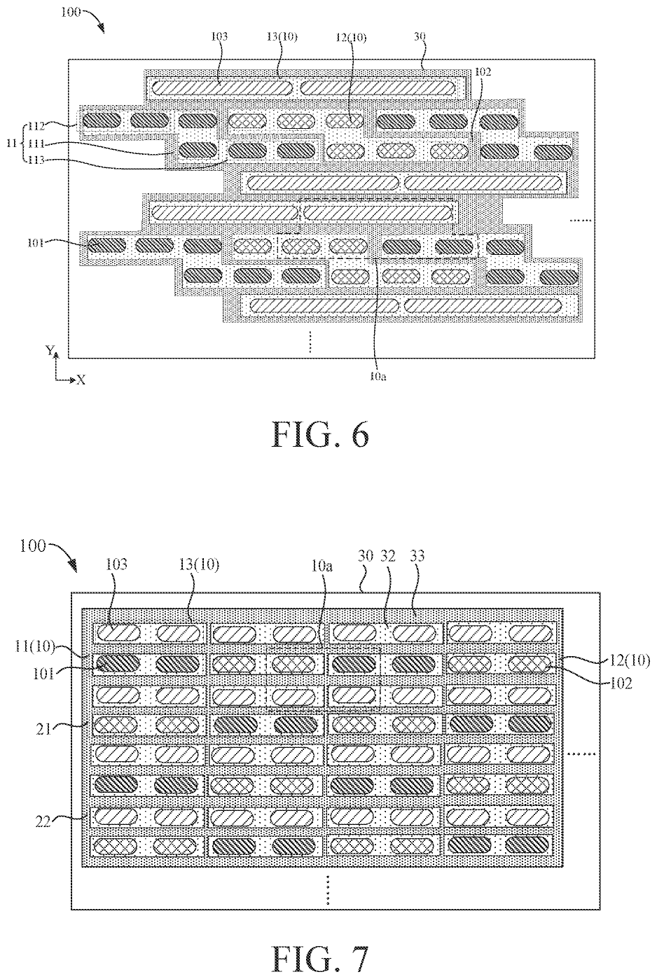

FIG. 6 is a fourth schematic structural diagram of a display panel provided by the present application.

FIG. 7 is a schematic diagram of a fifth structure of the display panel provided by the present application.

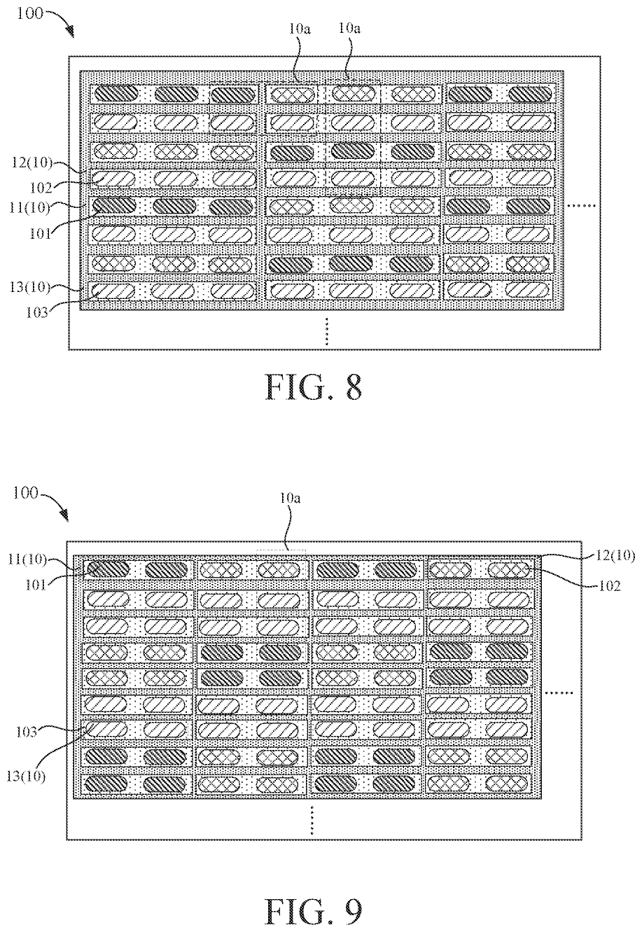

FIG. 8 is a sixth schematic structural diagram of the display panel provided by the present application.

FIG. 9 is a seventh structural schematic diagram of a display panel provided by the present application.

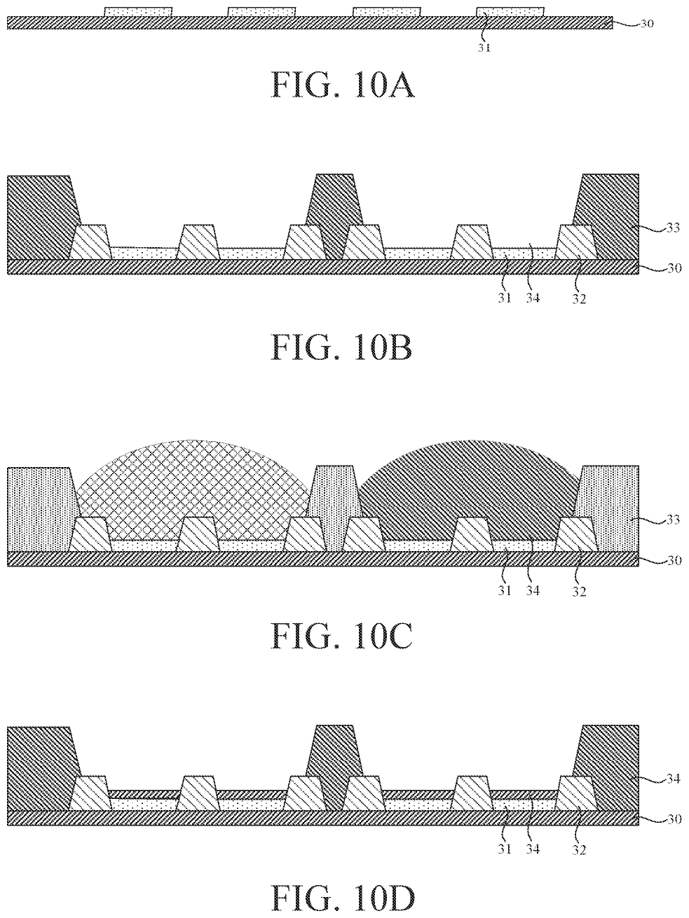

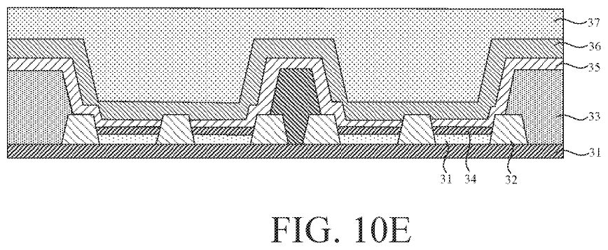

FIG. 10A to FIG. 10E are schematic diagrams of a manufacturing process of a display panel provided by the present application.

### EMBODIMENTS OF INVENTION

### Detailed Description of Preferred Embodiments

The technical solutions in the embodiments of the present application will be clearly described with reference to the drawings in the embodiments of the present application. Obviously, the embodiments are only a part of the embodiments of the present application, rather than all the embodiments. Based on the embodiments in the present application, all other embodiments obtained by one skilled in the art without doing creative efforts shall fall within the protection scope of this application. In addition, the specific embodiments described herein are only used to illustrate and explain the present application, but not to limit the present application. In this application, unless otherwise stated, the directional words such as “top”, “bottom”, “left”, or “right” usually refers to the top, bottom, left, or right when the device is used or in printing condition, and specifically refers to the directions in the drawings.

The present application provides a display panel, which will be described in detail below. It should be noted that the description order of the embodiments is not intended to limit the preferred order of the embodiments of the present application. In addition, in the following embodiments, the description of each embodiment has its own emphasis, and for parts that are not described in detail in a certain embodiment, reference may be made to the relevant descriptions of other embodiments.

Please refer to FIG. 1 and FIG. 2. FIG. 1 is a schematic top view of a first structure of a display panel provided by the present application. FIG. 2 is a schematic cross-sectional view of the display panel along AA′ in FIG. 1 provided by the present application. In the embodiment of the present application, the display panel 100 includes a substrate 30 and a plurality of pixel groups 10. A plurality of pixel groups 10 are provided on the substrate 30. The pixel group 10 includes a first pixel group 11, a second pixel group 12, and a third pixel group 13. The first pixel groups 11 and the second pixel groups 12 are alternately arranged along the second direction to form first pixel rows 21. The third pixel groups are alternately arranged along the second direction to form second pixel rows. Along the first direction, at least one second pixel row 22 is arranged between every two adjacent first pixel rows 21.

The first pixel group 11 includes at least two first sub-pixels 101 arranged along the second direction. The second pixel group 12 includes at least two second sub-pixels 102 arranged along the second direction. The third pixel group 13 includes at least one third sub-pixel 103 arranged along the second direction. The second direction intersects the first direction.

The first direction is a direction extending along the Y-axis, and the second direction is a direction extending along the X-axis. Optionally, the first direction and the second direction intersect vertically, which may be specifically set according to the specifications of the display panel 100. Certainly, in some embodiments, the second direction may also be a direction extending along the Y-axis, and the first direction may be a direction extending along the X-axis. It should be noted that the embodiments of the present application are described by taking the first direction as the direction extending along the Y-axis and the second direction as the direction extending along the X-axis as an example, which should not be construed as a limitation of the present application.

In the display panel 100 provided by the embodiment of the present application, the first pixel group 11 includes at least two first sub-pixels 101 arranged along the second direction and the second pixel group 12 includes at least two second sub-pixels 102 arranged along the second direction. In the first aspect, when the inkjet printing is performed on the first pixel group 11 and the second pixel group 12 along the first direction, in the direction perpendicular to the inkjet printing direction, the printing ranges corresponding to at least the first pixel group and the second pixel group, are effectively guaranteed. In the second aspect, the inkjet printing device can be suitable for printing the first sub-pixel 101 and the second sub-pixel 102 with smaller sizes under the condition that the volume of a single droplet ejected, the impact accuracy, and hardware accuracy of the inkjet printing device remain unchanged, thereby improving the pixel resolution of the display panel 100. In the third aspect, due to the nozzle hardware processing, the volume of each nozzle will be slightly different. Therefore, when the number of printing nozzles is more, the printing volume can be averaged, so the problem of uneven film thickness caused by the volume difference of different nozzles can be compensated, and the color uniformity of the display panel 100 can be improved. In addition, because the first pixel group 11 and the second pixel group 12 are located in the first pixel row 21 and are alternately arranged, when the first pixel group 11, the second pixel group 12, or the third pixel group 13 is abnormally printed, only the adjacent pixel groups 10 are affected, and will not affect the pixel groups 10 in an excessively large range, thereby improving the product yield.

In the embodiment of the present application, the first pixel groups 11, the second pixel groups 12, and the third pixel groups 13 respectively display different colors. The first sub-pixels 101, the second sub-pixels 102, and the third sub-pixels 103 may be one of red sub-pixels, blue sub-pixels, or red sub-pixels, respectively.

In the embodiment of the present application, because the third pixel group 13 is individually arranged in the second pixel row 22, the number of the third sub-pixels 103 in the third pixel group 13 is not limited. For example, the second pixel row 22 may be constituted by only one third pixel group 13. Thus, the printing efficiency of the third pixel group 13 can be improved to the greatest extent.

In the embodiment of the present application, the display panel 100 further includes a first retaining wall 32 and a second retaining wall 33. The first retaining wall 32 is disposed on the substrate 30 and at least located in the gap between adjacent sub-pixels (the first sub-pixel 101, the second sub-pixel 102, or the third sub-pixel 103) in the same pixel group 10. The second retaining wall 33 is disposed on the substrate 30 and located in the gap between adjacent pixel groups 10. The height of the first retaining wall 32 is smaller than the height of the second retaining wall 33.

In this embodiment of the present application, only the second retaining wall 33 may be provided between adjacent pixel groups 10. Alternatively, the first retaining wall 32 is also located in a partial space between adjacent pixel groups 10, that is, the first retaining wall 32 is disposed not only between adjacent sub-pixels but also between adjacent pixel groups 10. The second retaining wall 33 covers at least part of the first retaining wall 32 and the substrate 30. Alternatively, the gaps between adjacent pixel groups 10 are all provided with first retaining walls 32, and the second retaining walls 33 are provided above the first retaining walls 32. Therefore, the height difference between the first retaining wall 32 and the second retaining wall 33 is increased to avoid color mixing between adjacent pixel groups 10 during printing.

In this embodiment of the present application, the display panel 100 further includes, but is not limited to, an anode 31, a light-emitting layer 34, an electron transport layer/electron injection layer 35, a cathode 36, and an encapsulation layer 37.

Wherein, a plurality of anodes 31 are arranged on the substrate 30 at intervals. In each pixel group 10, a first retaining wall 32 is disposed between two adjacent anodes 31. Each light-emitting layer 34 is disposed on a side of a corresponding anode 31 away from the substrate 30. The electron transport layer/electron injection layer 35 is disposed on the side of the light-emitting layer 34 away from the substrate 30 and covers the first retaining wall 32, the second retaining wall, and the light-emitting layer 34. The cathode 36 is provided on the side of the electron transport layer/electron injection layer 35 away from the substrate 30.

Certainly, the cross-sectional structure of the display panel 100 shown in FIG. 2 is only for the convenience of understanding the arrangement of the pixel group 10, and should not be construed as a limitation of the present application. In some embodiments of the present application, the display panel 100 may not include the electron transport layer/electron injection layer 35. Alternatively, a hole transport layer and a hole injection layer may also be provided between anode 31 and the light-emitting layer 34, which are not specifically limited in this application.

In the embodiment of the present application, the height of the first retaining wall 32 ranges from 0.3 μm to 0.6 μm. The height of the second retaining wall 33 ranges from 0.9 μm to 1.2 μm. The height of the light-emitting layer 34 ranges from 10 nm to 200 nm. For example, the height of the first retaining wall 32 may be 0.3 μm, 0.4 μm, 0.5 μm, 0.6 μm, or the like. The height of the second retaining wall 33 may be 0.9 μm, 1 micrometer, 1.1 μm, 1.2 μm, or the like. The height of the light-emitting layer 34 may be 10 nm, 50 nm, 100 nm, 150 nm, 200 nm, or the like.

It can be understood that when inkjet printing is performed on each pixel group 10 by the inkjet printing technology, the luminescent material may remain on the upper surface of the first retaining wall 32, but it does not affect the distinction of multiple sub-pixels in each pixel group 10, because each sub-pixel emits light only in the area corresponding to the anode 31. In addition, in the embodiment of the present application, the height of the second retaining wall 33 is set to be greater than the height of the first retaining wall 32, which can effectively avoid color mixing between adjacent pixel groups 10.

In addition, in the embodiment of the present application, the substrate 30 may be an array substrate. The array substrate is provided with functional layers such as driving transistors to drive the pixel group 10 to emit light normally. For example, the array substrate includes but is not limited to a substrate, a light-shielding layer disposed on the substrate, a buffer layer disposed on the substrate and covering the light-shielding layer, an active layer, a gate insulating layer, and a gate sequentially stacked on the buffer layer from bottom to top, an interlayer dielectric layer disposed above the buffer layer and covering the active layer, the gate insulating layer, and the gate. Wherein, the active layer includes a channel region, and a source region and a drain region located on both sides of the channel region. The source and the source region arranged on an interlayer dielectric layer are electrically connected. The drain and the drain region disposed on the interlayer dielectric layer are electrically connected. The source and the drain may also be covered with a passivation layer and/or a planarization layer arranged in layers. The anode is disposed on the passivation layer or the planarization layer.

Please refer to FIG. 1 and FIG. 2, in the first pixel group 11, the plurality of first sub-pixels 101 are arranged in two rows along the first direction, and the number of the first sub-pixels 101 in each row is equal. In the second pixel group 12, a plurality of second sub-pixels 102 are arranged in two rows along the first direction, and the number of second sub-pixels 102 in each row is equal. In the third pixel group 13, a plurality of third sub-pixels 103 are arranged in a row along the first direction.

That is, each first pixel group 11 includes an even number of first sub-pixels 101, each second pixel group 12 includes an even number of second sub-pixels 102, and the arrangement of the third sub-pixels 103 in the third pixel group 13 can be set according to the structures of the first sub-pixels 101 and the second sub-pixels 102.

Specifically, in the embodiment of the present application, in the first pixel group 11 and the second pixel group 12, the first sub-pixels 101 and the second sub-pixels 102 are arranged in an axisymmetric arrangement. The symmetry axis extends in the first direction or the second direction. Along the second direction, the first pixel group 11 and the second pixel group 12 are located in different columns, and the dotted box M in FIG. 1 represents a column. In this situation, in the third pixel group 13, the third sub-pixels 103 are arranged in a row along the first direction. At least one second pixel row 22 is arranged between every two adjacent first pixel rows 21.

For example, as shown in FIG. 1, the first pixel group 11 includes four first sub-pixels 101, the second pixel group 12 includes four second sub-pixels 102, and each third pixel group includes four third sub-pixels 103. The first sub-pixels 101, the second sub-pixels 102, and the third sub-pixels 103 are arranged in an array. A second pixel row 22 is arranged between every two adjacent first pixel rows 21, wherein, the areas of each of the first sub-pixels 101, each of the second sub-pixels 102, and each of the third sub-pixels 103 are equal.

The first sub-pixel 101, the second sub-pixel 102, and the third sub-pixel 103 may be one of a red sub-pixel, a green sub-pixel, or a blue sub-pixel, respectively. Each adjacent one first sub-pixel 101, one second sub-pixel 102, and one third sub-pixel 103 constitute one pixel unit 10a.

Certainly, when the third sub-pixel 103 is a blue sub-pixel, since the luminous intensity of the blue sub-pixel is relatively weak, a plurality of second pixel rows 22 may be arranged between every two adjacent first pixel rows 21. In this situation, each adjacent first sub-pixel 101, a second sub-pixel 102, and a plurality of third sub-pixels 103 constitute a pixel unit 10a, thereby improving the light-emitting effect of the pixel unit 10a.

Furthermore, because the second pixel row 22 is constituted only by the third pixel group 13, each third pixel group 13 may also include 2 third sub-pixels 103, 6 third sub-pixels 103, 8 third sub-pixels 103, a row of third sub-pixels 103, etc. This application does not specifically limit this.

For another example, please refer to FIG. 3, which is a schematic diagram of the second structure of the display panel provided by the present application. The difference from the display panel 100 shown in FIG. 1 is that, in the embodiment of the present application, the first pixel group 11 includes six first sub-pixels 101, and the second pixel group 12 includes six second sub-pixels 102. Along the second direction, the plurality of first pixel groups 11 and the plurality of second pixel groups 12 are alternately arranged along the first direction.

Wherein, along the first direction, each adjacent first sub-pixel 101, second sub-pixel 102, and third sub-pixel 103 constitutes a pixel unit 10a. Similarly, in each third pixel group 13, the number of the third sub-pixels 103 can be set according to the actual situation. The areas of each of the first sub-pixels 101, each of the second sub-pixels 102, and each of the third sub-pixels 103 are equal. Certainly, due to reasons such as process tolerance, equal areas can also be understood as approximately equal.

Please refer to FIG. 4, which is a schematic diagram of a third structure of the display panel provided by the present application. The difference from the display panel 100 shown in FIG. 1 is that, in the embodiment of the present application, along the second direction, the display panel 100 has a first end 100a and a second end 100b disposed opposite to each other. The first pixel group 11 includes a first pixel structure 111, a second pixel structure 112, and a third pixel structure 113. The first pixel structure 111 extends along the first direction. The second pixel structure 112 extends from the first pixel structure 111 to the first end 100a. The third pixel structure 113 extends from the first pixel structure 111 to the second end 100b. The second pixel structure 112 and the third pixel structure 113 are located in different rows. The first pixel structure 111 and the third pixel structure 113 are pixel combinations with different arrangement shapes composed of at least one first sub-pixel 101. Both the first pixel structure 111 and the second pixel structure 112 are a pixel combination composed of at least one first sub-pixel 101 with the same arrangement shape.

That is, the plurality of first sub-pixels 101 in the first pixel group 11 are arranged in a “Z” shape. The second pixel group 12 has the same structure as the first pixel group 11 and is also arranged in a “Z” shape, which is not repeated herein. Two second pixel rows 22 are arranged between every two adjacent first pixel rows 21. Each third sub-pixel 103 is arranged corresponding to one first sub-pixel 101 and one second sub-pixel 102.

The first sub-pixel 101 is one of a red sub-pixel or a green sub-pixel. The second sub-pixel 102 is the other of the red sub-pixel or the green sub-pixel. The third sub-pixel 103 is a blue sub-pixel.

It can be understood that due to the characteristics of RGB materials, the fluorescence lifetimes of the green sub-pixels and the red sub-pixels are longer than the fluorescence lifetimes of the blue sub-pixels. Therefore, one third sub-pixel 103 is arranged corresponding to one first sub-pixel 101 and one second sub-pixel 102, so that the area of each third sub-pixel 103 is larger than the area of each first sub-pixel 101, and the area of each third sub-pixel 103 is larger than the area of each second sub-pixel 102, so as to balance the luminous lifetime of each sub-pixel and ensure the uniformity of the luminous emission of the display panel 100.

Certainly, in other embodiments of the present application, the extension length of the third sub-pixel 103 along the first direction may also be increased, so that the light-emitting area of the third sub-pixel 103 is maximized.

Further, as shown in FIG. 4, in this embodiment of the present application, the first pixel structure 111 includes two first sub-pixels 101 arranged along the first direction. Both the second pixel structure 112 and the third pixel structure 113 include one first sub-pixel 101. The third pixel group 13 includes two third sub-pixels 103. Each of the third sub-pixels 103 and one of the first sub-pixels 101 and one of the second sub-pixels 102 adjacent to each other form a pixel unit 10a.

Please refer to FIG. 5. It can be understood that FIG. 5 is a schematic diagram of the principle of inkjet printing on a display panel provided by the present application. Wherein, the inkjet printing process usually uses an inkjet printing device (not shown in the figure). The inkjet printing device includes a plurality of printheads 40. Only one printhead 40 is shown in FIG. 5 for illustration, and should not be construed as a limitation to the present application. Generally, for the consideration of printing stability, the printhead 40 is fixed, and the display panel 100 moves along a direction perpendicular to the printing direction.

Wherein, each printhead 40 includes a plurality of nozzles 41. The printhead 40 ejects printing materials through a plurality of nozzles 41 to print the display panel 100 to be printed. For example, when an inkjet printing device is used to print the pixel group 10 of the display panel 100, the printing material may be a red light-emitting material, a green light-emitting material, a blue light-emitting material, a white light-emitting material, or the like.

The traditional SBS architecture is to define pixel openings on the entire pixel definition layer, and the luminescent material is printed in the openings. However, the luminescent materials of the same color are separated by the pixel definition layer to form a plurality of independently distributed sub-pixels, which cannot realize the continuous printing of the inkjet printing process and reduces the printing efficiency. Therefore, compared with the current SBS architecture, there are only two nozzles 41 for printing each sub-pixel, in the embodiment of the present application, when each pixel group 10 includes at least two sub-pixels arranged along the second direction, there are at least 4 nozzles 41 corresponding to each pixel group to simultaneously eject the printing material. Further, when a plurality of sub-pixels are arranged in a “Z” shape, there may be at least six nozzles 41 corresponding to each pixel group 10 to simultaneously eject printing materials. This ensures that each pixel group 10 has a sufficient printing range during inkjet printing. Thus, the utilization rate of the nozzles 41 is improved, and the inkjet printing time is reduced.

Please refer to FIG. 6, which is a fourth schematic structural diagram of a display panel provided by the present application. The difference between the display panel 100 shown in FIG. 6 and the display panel 100 shown in FIG. 4 is that, in this embodiment of the present application, the first pixel structure 111 includes two first sub-pixels 101 arranged along the first direction. Both the second pixel structure 112 and the third pixel structure 113 include two first sub-pixels 101 arranged along the second direction. The third pixel group 13 includes two third sub-pixels 103.

Wherein, the area of each first sub-pixel 101 is equal to the area of each second sub-pixel 102. The area of each third sub-pixel 103 is larger than that of each first sub-pixel 101 (each second sub-pixel 102). Specifically, one third sub-pixel 103 is arranged corresponding to at least one first sub-pixel 101 and at least one second sub-pixel 102. The area of the third sub-pixel 103 is larger than that of the first sub-pixel 101, and the area of the third sub-pixel 103 is larger than that of the second sub-pixel 102 so as to balance the light-emitting lifetime of each sub-pixel.

Wherein, each third sub-pixel 103 and adjacent two first sub-pixels 101 or two second sub-pixels 102 constitute a pixel unit 10a. Two adjacent third sub-pixels 103 located in the same row share one first sub-pixel 101 or second sub-pixel 102.

By sharing the first sub-pixel 101 or the second sub-pixel 102 between adjacent pixel units 10a in the pixel architecture in the embodiment of the present application, the pixel resolution of the display panel 100 can be further improved. In addition, the embodiment of the present application makes the number and arrangement of the first sub-pixels 101, the second sub-pixels 102, or the third sub-pixels 103 in the pixel group 10 more flexible.

Please refer to FIG. 7. FIG. 7 is a schematic diagram of a fifth structure of the display panel provided by the present application. The difference between FIG. 7 and the display panel 100 shown in FIG. 1 is that, in this embodiment of the present application, in the first pixel group 11, a plurality of first sub-pixels 101 are arranged in a row along the first direction. In the second pixel group 12, the plurality of second sub-pixels 102 are arranged in a row along the first direction. The first pixel rows 21 and the second pixel rows 22 are alternately arranged along the first direction. Wherein, the areas of each of the first sub-pixels 101, each of the second sub-pixels 102, and each of the third sub-pixels 103 are equal.

Further, in some embodiments of the present application, as shown in FIG. 7, the first pixel group 11 includes two first sub-pixels 101. The second pixel group 12 includes two second sub-pixels 102. The third pixel group 13 includes two third sub-pixels 103. The first sub-pixels 101, the second sub-pixels 102, and the third sub-pixels 103 are arranged in an array. One first sub-pixel 101, one second sub-pixel 102, and two third sub-pixels 103 adjacent to each other constitute a pixel unit 10a.

Wherein, along the first direction, the first pixel groups 11 located in the first pixel rows 21 of two adjacent rows are alternately arranged. Certainly, in other embodiments, the first pixel groups 11 located in the first pixel rows 21 of two adjacent rows can also be arranged in a one-to-one correspondence.

In other embodiments of the present application, please refer to FIG. 8. FIG. 8 is a schematic diagram of a sixth structure of the display panel provided by the present application. The difference between the display panel 100 shown in FIG. 8 and the display panel 100 shown in FIG. 7 is that, in this embodiment of the present application, the first pixel group 11 includes three first sub-pixels 101, the second pixel group 12 includes three second sub-pixels 102, and the third pixel group 13 includes three third sub-pixels 103. Wherein, the areas of each of the first sub-pixels 101, each of the second sub-pixels 102, and each of the third sub-pixels 103 are equal.

Wherein, a first sub-pixel 101, a second sub-pixel 102, and two third sub-pixels 103 adjacent to each other constitute a pixel unit 10a. It should be noted that, in the embodiment of the present application, the pixel unit 10a has two forms, which are specifically shown by the dotted box in FIG. 8. This embodiment of the present application makes the arrangement of the first sub-pixels 101, the second sub-pixels 102, or the third sub-pixels 103 in the pixel group 10 more flexible.

Certainly, in other embodiments of the present application, the first pixel group 11 may further include more than three first sub-pixels 101. The second pixel group 12 may also include more than three second sub-pixels 102. The third pixel group 13 may also include more than three third sub-pixels 103. This will not be repeatedly described herein.

Please refer to FIG. 9, which is a seventh structural schematic diagram of a display panel provided by the present application. The difference between the display panel shown in FIG. 9 and FIG. 7 is that in this embodiment of the present application, along the first direction, in each adjacent four-row pixel group, two second pixel rows are arranged between two first pixel rows.

The first sub-pixel 101 is one of a red sub-pixel or a green sub-pixel. The second sub-pixel 102 is the other of the red sub-pixel or the green sub-pixel. The third sub-pixel 103 is a blue sub-pixel. One first sub-pixel 101, one second sub-pixel 102, and two third sub-pixels 103 adjacent to each other constitute a pixel unit 10a. It should be noted that the dotted box in FIG. 9 shows only one structure of the pixel unit 10a. In other embodiments of the present application, the pixel unit 10a may also have a 2 by 2 matrix structure as shown in FIG. 7.

It can be known from the foregoing analysis that the third sub-pixel 103 is a blue sub-pixel. One pixel unit 10a includes two third sub-pixels 103, which can improve the light-emitting effect of the pixel unit 10a. Wherein, the areas of each of the first sub-pixels 101, each of the second sub-pixels 102, and each of the third sub-pixels 103 are equal.

Correspondingly, the present application further provides a manufacturing method of a display panel. Specifically, please refer to FIG. 1 and FIG. 10A to FIG. 10E. FIG. 10A to FIG. 10E are schematic diagrams of a manufacturing process of a display panel provided by the present application. Wherein, the manufacturing method of the display panel 100 includes the following steps:

Step 101, providing a substrate.

Wherein, the substrate 30 may include a base and functional film layers such as driving transistors disposed on the base. For details, please refer to the above content, which will not be repeated herein.

Step 102, forming a plurality of pixel groups 10 on the substrate. A plurality of pixel groups 10 are disposed on the substrate 30 and arranged in a first direction into a plurality of first pixel rows 21 and second pixel rows 22. The pixel group 10 includes a first pixel group 11, a second pixel group 12, and a third pixel group 13. The first pixel group 11 and the second pixel group 12 are located in the first pixel row 21 and alternately arranged along the second direction. The third pixel group 13 is located in the second pixel row 22. At least one second pixel row 22 is arranged between every two adjacent first pixel rows 21.

The first pixel group 11 includes at least two first sub-pixels 101 arranged along the second direction. The second pixel group 12 includes at least two second sub-pixels 102 arranged along the second direction. The third pixel group 13 includes at least one third sub-pixel 103 arranged along the second direction. The second direction intersects the first direction.

Specifically, step 102 specifically includes:

Please refer to FIG. 10A, forming a plurality of anodes 31 on the substrate 30, which are arranged at intervals.

As shown in FIG. 10B, the first retaining wall 32 is formed on the substrate 30 by an exposure and development process. The first retaining wall 32 is located at a gap between adjacent anodes 31. A plurality of second retaining walls 33 are formed on the substrate 30 by an exposure and development process. The second retaining wall 33 is located at a gap between adjacent pixel groups 10 and covers at least part of a corresponding first retaining wall 32.

That is, by forming the patterned first retaining walls 32 and the second retaining walls 33, a plurality of pixel groups 10 may be formed in the display panel 100, and a plurality of sub-pixels may be formed in each pixel group 10. Wherein, the heights of the second retaining wall 33 and the first retaining wall 32 can be referred to the afore-said embodiments, which will not be repeated herein.

As shown in FIG. 10C, a corresponding light-emitting layer 34 is formed on the side of each anode 31 away from the substrate 30 by an inkjet printing process.

Wherein, due to the blocking effect of the second retaining wall 33, no color mixing occurs between adjacent pixel groups 10. In the same pixel group 10, due to the arrangement of the first retaining wall 32, the printed luminescent material can flow to form a plurality of luminescent layers 34 corresponding to the anodes 31 in one-to-one correspondence.

Finally, as shown in FIG. 10E, a cathode 36 is formed on the side of the light-emitting layer 34 away from the substrate 30 by vapor deposition or magnetron sputtering. An encapsulation layer 37 is formed on the side of the cathode 36 away from the substrate 30. The encapsulation layer 37 may adopt the manner of stacking inorganic/organic/inorganic materials, which is not specifically limited in this application.

Certainly, in the embodiment of the present application, a hole injection layer/hole transport layer may also be formed between anode 31 and the light-emitting layer 34 by using an inkjet printing process, and/or the electron transport layer/electron injection layer 35 is formed between the light-emitting layer 34 and the cathode 36 by inkjet printing or evaporation.

In the above method, the display panels 100 with different pixel structures provided by the embodiments of the present application can be realized by changing the patterning manner of the first retaining wall 32 and the second retaining wall 33, which will not be described herein.

In the display panel 100 manufactured in the embodiment of the present application, the first pixel group 11 includes at least two first sub-pixels 101 arranged along the second direction, and the second pixel group 12 includes at least two second sub-pixels 102 arranged along the second direction. On the one hand, when inkjet printing is performed along the first direction, the printing range corresponding to at least the first pixel group 11 and the second pixel group 12 is effectively guaranteed along the direction perpendicular to the printing direction. This improves the utilization of printing nozzles, reduces inkjet printing time, and is suitable for printing the first sub-pixel 101 and the second sub-pixel 102 with smaller sizes, thereby improving pixel resolution. On the other hand, since the first pixel group 11 and the second pixel group 12 are located in the first pixel row 21 and are alternately arranged, when the first pixel group 11, the second pixel group 12, or the third pixel group 13 is abnormally printed, it will not affect a wide range of pixel areas, which improves the product yield.

This article introduces the display panel provided by the present application in detail and uses specific examples to illustrate the principles and implementations of the present application. The descriptions of the embodiments are only used to help understand the method of the present application and its core idea. Meanwhile, for one of ordinary skill in the art, according to the idea of the present application, there will be changes in the specific embodiments and the scope of application. In conclusion, the content of this specification should not be construed as a limitation on the present application.

What is claimed is:

1. A display panel, comprising:
a substrate;
a plurality of pixel groups arranged on the substrate and comprising first pixel groups, second pixel groups, and third pixel groups, wherein the first pixel groups and the second pixel groups are alternately arranged along a second direction to form first pixel rows, and the third pixel groups are arranged along the second direction to form second pixel rows, wherein at least one of the second pixel rows is arranged between two adjacent ones of the first pixel rows along a first direction, and wherein the second direction intersects with the first direction; and
wherein each first pixel group comprises at least two first sub-pixels arranged along the second direction, each second pixel group comprises at least two second sub-pixels arranged along the second direction, and each third pixel group comprises at least one third sub-pixels arranged along the second direction.

2. The display panel of claim 1, wherein the first sub-pixels are arranged in two rows along the first direction in the first pixel group, and numbers of the first sub-pixels in each row are equal, wherein the second sub-pixels are arranged in two rows along the first direction in the second pixel group, and numbers of the second sub-pixels in each row are equal, and wherein the third sub-pixels are arranged in a row along the first direction in the third pixel group.

3. The display panel of claim 2, wherein in the first pixel group and the second pixel group, the first sub-pixels and the second sub-pixels are arranged axially symmetrically, and the first pixel group and the second pixel group are alternately arranged along the first direction.

4. The display panel of claim 2, wherein the first sub-pixels and the second sub-pixels are arranged axially symmetrically in the first pixel group and the second pixel group, and the first pixel group and the second pixel group are located on different columns along the second direction.

5. The display panel of claim 2, further comprising a first end and a second end arranged oppositely along the second direction, wherein the first pixel group comprises a first pixel structure, a second pixel structure, and a third pixel structure, wherein the first pixel structure extends along the first direction, the second pixel structure extends from the first pixel structure to the first end, and the third pixel structure extends from the first pixel structure to the second end, wherein the second pixel structure and the third pixel structure are located on different rows, and wherein the second pixel group has a same structure as the first pixel group; and
wherein two of the second pixel rows are arranged between two adjacent ones of the first pixel rows, and each of the third sub-pixels is disposed corresponding to one of the first sub-pixels and one of the second sub-pixels.

6. The display panel of claim 2, wherein each of the first sub-pixels and each of the second sub-pixels have an equal area.

7. The display panel of claim 6, wherein the second pixel rows are arranged between two adjacent ones of the first pixel rows, and wherein one of the first sub-pixels, one of the second sub-pixels, and one of the third sub-pixels adjacent to each other constitute a pixel unit.

8. The display panel of claim 5, wherein the first pixel structure comprises two of the first sub-pixels arranged along the first direction, both the second pixel structure and the third pixel structure comprise one of the first sub-pixels, and the third pixel group comprises two of the third sub-pixels.

9. The display panel of claim 8, wherein the first pixel structure comprises two of the first sub-pixels arranged along the first direction, both the second pixel structure and the third pixel structure comprise two of the first sub-pixels arranged along the second direction, and the third pixel group comprises two of the third sub-pixels.

10. The display panel of claim 9, wherein an area of each first sub-pixel is equal to an area of each second sub-pixel, and an area of each third sub-pixel is greater than the area of each first sub-pixel.

11. The display panel of claim 1, wherein the first sub-pixels are arranged in a row along the first direction in the first pixel group, and the second sub-pixels are arranged in a row along the first direction in the second pixel group, and wherein the first pixel rows and the second pixel rows are alternately arranged along the first direction.

12. The display panel of claim 11, wherein the first pixel group located on two adjacent ones of the first pixel rows are arranged in a one-to-one correspondence or staggered along the first direction.

13. The display panel of claim 1, wherein the first sub-pixels in the first pixel group are arranged in a row along the first direction, the second sub-pixels in the second pixel group are arranged in a row along the first direction, and in every adjacent four rows of the plurality of pixel groups, two of the second pixel rows are arranged between two of the first pixel rows along the first direction; and
wherein the first sub-pixels are one of red sub-pixels or green sub-pixels, the second sub-pixels are another one of the red sub-pixels or the green sub-pixels, and the third sub-pixels are blue sub-pixels, and wherein one of the first sub-pixels, one of the second sub-pixels, and two of the third sub-pixels adjacent to each other constitute a pixel unit.

14. The display panel of claim 13, wherein the first pixel group located on two adjacent ones of the first pixel rows are arranged in a one-to-one correspondence or staggered along the first direction.

15. The display panel of claim 1, further comprising a first retaining wall and a second retaining wall, wherein the first retaining wall is disposed on the substrate and is located in a gap between adjacent sub-pixels in one of the plurality of pixel groups, wherein the second retaining wall is disposed on the substrate and is located in a gap between adjacent ones of the plurality of pixel groups, and wherein a height of the first retaining wall is smaller than a height of the second retaining wall.

16. The display panel of claim 15, wherein the first retaining wall is further located between adjacent ones of the plurality of pixel groups, and the second retaining wall covers at least part of the first retaining wall.

17. The display panel of claim 15, wherein a height of the first retaining wall ranges from 0.3 to 0.6 μm, and a height of the second retaining wall ranges from 0.9 to 1.2 μm.

18. The display panel of claim 15, further comprising anodes, light-emitting layers, and a cathode, wherein the anodes are arranged on the substrate at intervals, wherein in each of the plurality of pixel groups, the first retaining wall is arranged between two adjacent ones of the anodes, and each of the light-emitting layers is arranged on a side of a corresponding one of the anodes away from the substrate, and wherein the cathode is disposed on a side of one of the light-emitting layers away from the substrate and covers the first retaining wall, the second retaining wall, and the light-emitting layer.

19. The display panel of claim 18, wherein a height of the light-emitting layer ranges from 10 nm to 200 nm.

20. The display panel of claim 1, wherein the first pixel groups, the second pixel groups, and the third pixel groups display different colors, respectively.
